(19) United States
(12) Patent Application Publication
(10) Pub. No.: US 2017/0150556 A1
(43) Pub. Date: May 25, 2017

(54) ELECTRIC ARC FURNACE COMPRISING A SAFETY DEVICE, AND A METHOD FOR PROTECTING PERIPHERAL DEVICES ON ELECTRIC ARC FURNACES

(71) Applicant: Primetals Technologies Germany GmbH, Erlangen (DE)

(72) Inventors: Werner HARTMANN, Weisendorf (DE); Vico HAVERKAMP, Hamburg (DE); Martin HERGT, Nürnberg (DE); Klaus KRÜGER, Saaldorf-Surheim (DE); THomas MATSCHULLAT, Eckental (DE)

(73) Assignee: Primetals Technologies Germany GmbH, Erlangen (DE)

(21) Appl. No.: 15/323,850

(22) PCT Filed: Jul. 14, 2015
(86) PCT No.: PCT/EP2015/066014

§ 371 Date: Jan. 4, 2017

(30) Foreign Application Priority Data
Jul. 15, 2014 (DE) 10 2104 213 744.6

(51) Int. Cl. H05B 7/148; G01R 31/02; F27B 3/28

(52) U.S. Cl. CPC H05B 7/148; F27B 3/28; G01R 31/02; F27D 2021/0057

(57) ABSTRACT

An electric arc furnace has a safety device (3) connected to an earthed peripheral device. An earth cable (4) is provided to the peripheral device of the arc furnace (2). An ammeter (6) measures the current across the earth cable (4). A circuit breaker (8) in the earth cable (4) has a tripping time of less than 100 ms.

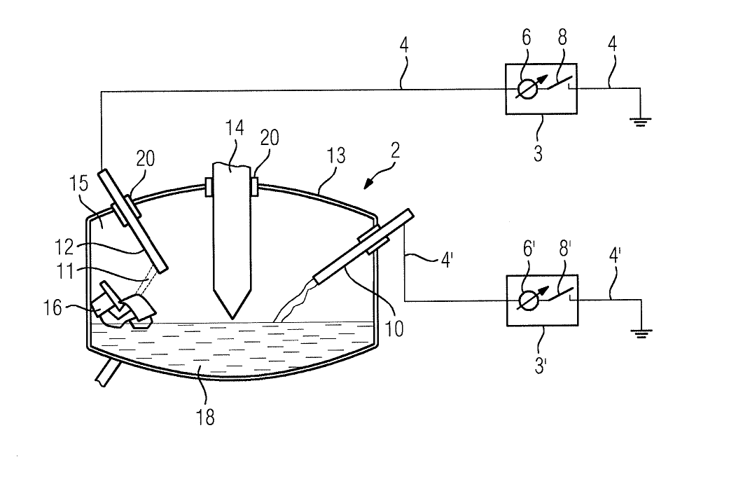

### CROSS-REFERENCE TO RELATED APPLICATIONS

The present application is a 35 U.S.C. §§371 national phase conversion of PCT/EP2015/066014, filed Jul. 14, 2015, which claims priority of German Patent Application No. 10 2014 213 744.6, filed July 15, 2014, the contents of which are incorporated by reference herein. The PCT International Application was published in the German language.

### TECHNICAL FIELD

The invention relates to an electric arc furnace having a safety device for halting current to parts of or in the furnace under determined conditions, and to a method for protecting peripheral devices on an electric arc furnace by use of the safety device.

### TECHNICAL BACKGROUND

Electric arc furnaces are used in the production of steel and other metals to melt scrap and other ferrous materials, or nickel or also chromium. During the melting procedure, part of the necessary thermal energy is often introduced by means of a gas burner in order to accelerate the melting procedure without having to increase the electrical connection power of the arc furnace. For the introduction of other materials, for example dust or oxygen to oxidize the melt, gas supply pipes referred to as lances or injectors are also required. In some cases, electrical burners—referred to as plasma burners—are also used in order to introduce the necessary process heat into the furnace. For reasons of electrical installation safety, all of these—and any other peripheral devices—must be earthed separately in the outer region of the arc furnace, in order to prevent, during operation, the occurrence of dangerous contact voltages at these parts and the associated lines or attachment structures. These peripheral devices with their lines and attachment structures are therefore generally at a different electrical potential to the furnace wall and in particular the charge material. Thus, during operation of the arc furnace, it can occasionally occur that a partial arc from the melt or the material to be melted, or from one of the arc electrodes, strikes these installation parts or peripheral devices, and a sizeable current of many kiloamperes in amplitude can discharge to earth. In particular, this can be triggered by scrap that is to be melted falling over in the scrapheap or being pushed aside and coming into proximity with the burner or with the lance, such that a fault arc can ignite. This can lead to substantial damage to the abovementioned peripheral devices. It also represents a considerable danger, for example due to steam explosions in the arc furnace, if the arc furnace causes the supply of cooling water for the burners or for a panel to be broken, and cooling water penetrates into the arc furnace.

Therefore, hitherto the water pressure and/or the return-flow temperature of the cooling water from said peripheral devices or from a panel has been monitored. In the event of problems arising, the furnace is switched off and the supply of cooling water is turned off. However, these methods frequently result in a relatively lengthy reaction time for reacting to partial arcs that have formed, which can lead to damage to the peripheral devices. Furthermore, switching off the arc furnace leads to a substantial loss of production.

### SUMMARY OF THE INVENTION

The object of the invention is to provide an electric arc furnace having a corresponding safety device, and a method for protecting an arc furnace, which represent improved protection for peripheral devices in comparison to the prior art. In addition, downtimes of the arc furnace during the process are to be minimized.

The problem is solved with an electric arc furnace having a safety device having the features disclosed herein, and with a method for protecting peripheral devices on an electric arc furnace, having the features disclosed herein and using the safety device.

The electric arc furnace herein disclosed has a safety device and at least one earthed peripheral device. The arc furnace has an earth line to the peripheral device, and furthermore has an ammeter for measuring the current in the earth line. The device further comprises a safety switch which is arranged in the earth line and therefore has a tripping time of less than 100 ms.

Thus, the current in the earth line is continuously monitored, and in the event of a partial arc forming between the melt or a scrap part and the peripheral device, this current in the earth line naturally increases very rapidly, and the safety switch is tripped in less than 100 ms, preferably in less than 10 ms. Thus, the earth line is briefly broken, preferably only for less than a second, such that the partial arc which has rapidly formed between the peripheral device and the charge material is immediately extinguished. This prevents any endangerment of the peripheral device at the first signs, since the quantity of energy required for permanent damage is not reached. It is then not necessary to switch off the entire arc furnace.

It is particularly advantageous if the ammeter is already integrated into the safety switch, since it is thus possible to further reduce the reaction times of the safety switch.

The peripheral devices of the arc furnace are in particular a lance, an injector or a burner. It is also possible for cooling panels of the arc furnace to be protected by means of the device according to the invention.

In another embodiment of the invention, the peripheral device of the arc furnace is an electrically operated plasma burner or plasma injector which has, as its outer layer, a metal shell which is electrically insulated from the other burner parts, and only the insulated metal shell is electrically connected to the safety device.

Another constituent part of the invention is a method for protecting peripheral devices on an electric arc furnace. In this method, an earth line is provided on the peripheral device, and a flow of current through the earth line is measured in order that, in the event of a critical current magnitude, the earth line is broken by a safety switch within 100 ms.

The method according to the invention provides the same advantages as have already been described with regard to the device.

There follows a more detailed explanation of an exemplary embodiment of the invention with reference to the figure below. This is a general embodiment of the invention, which is illustrated in a simplified manner and represents no limitation of the scope of protection.

### DESCRIPTION OF THE DRAWING

The single figure shows an arc furnace having peripheral devices and safety devices.

### DESCRIPTION OF AN EMBODIMENT

An arc furnace 2 has an electrode 14 which is inserted through insulation 20 in a roof 13 of the arc furnace 2 into an interior 15 of the arc furnace 2 and serves for the transfer of electrical current for heating charge material 16. Furthermore, various peripheral devices are shown schematically and by way of example, one of these is a gas burner 10 which serves for additionally heating the charge material 16 and for converting the charge material 16 into the melt 18. Also illustrated schematically is an oxygen lance 20 which serves for introducing oxygen into the melt. Both the burner 10 and the lance 12 are introduced through insulation in the cooled roof 13 of the arc furnace 2.

The peripheral devices, illustrated here by the example of the burner 10 and the lance 12, are electrically insulated from the arc furnace 2, for which reason they are earthed separately, for safety reasons, via the earth line 4. In the earth line 4 or, respectively, 4′ there is provided a safety device 3 or, respectively, 3′ which is configured in the form of a safety switch 8 and an integrated ammeter 6. In the event of a partial arc 11, indicated schematically by the dashed line 11 between the charge material 16 and the lance 12, a substantial current flows through the earth line 4, is detected by the ammeter 6 and causes the safety switch 8 to open in less than 100 ms, preferably in less than 10 ms. The earth line 4, 4′ is thus broken within a few milliseconds and the partial arc 11 collapses, preferably before it has fully built up. This prevents damage to the peripheral device, in this example the lance 12, by immediately breaking the earth line.

In that context, the earth line is preferably broken only for a short time, that is to say only a few seconds, which is just long enough for the fault arc to extinguish, such that no primary or secondary damage to the other peripheral device can occur. The earth line 4 is preferably provided, in the vicinity of the arc furnace 2, with the corresponding safety switch 8 or the safety device 3. In the event of a fault, that is to say in the event of a fault arc 11 against the at-risk peripheral parts, the arc current discharging to earth through the safety switch 8 is limited within a few milliseconds and then interrupted, whereby primary damage also to a coolant supply in the roof 13 of the arc furnace 2 can be avoided, thus also avoiding fusing of this coolant supply, which is not shown in greater detail in the figure. This also increases safety with respect to possible steam explosions which can be caused by escaping cooling water.

It is also expedient for the safety switch 8 or the safety device 3 as a whole to be installed in the earth line 4 as close as possible to the furnace such that, in operation, it is impossible for persons to come into contact with the briefly non-earthed installation parts. The gas supply lines to the peripheral devices must be supplied, at least over short distances of at least a few centimeters, with sufficient insulation to insulate the corresponding voltages of a few 100 V up to 1 kV, and beyond this region be again earthed so as to be contact-safe.

### List of Reference Signs

2 Arc furnace
3 Safety device
4 Earth line
6 Ammeter
8 Safety switch
10 Burner
11 Partial arc
12 Oxygen lance
13 Cooled roof
14 Electrode
15 Interior
16 Scrap
18 Melt
20 Insulation

1. A safety device for an electric arc furnace having an arc electrode extending into the furnace configured for melting metal in the furnace, the safety device comprising:
an earthed peripheral device at a periphery of the furnace, spaced from the metal to be melted and from the arc electrode, and electrically insulated from the furnace;
an earth line to the peripheral device at the arc furnace and the earth line is grounded to earth;
an ammeter connected with the earth line for measuring electric current in the earth line to determine if an arc is forming in the furnace with the peripheral device; and
a safety switch in the earth line responsive to measurement by the ammeter, and the safety switch being configured to have a tripping time of less than 100 ms responsive to a preset measurement by the ammeter related to an arc forming.

2. The safety device as claimed in claim 1, further comprising the ammeter is integrated into the safety switch.

3. The safety device as claimed in claim 1, further comprising the peripheral device of the arc furnace comprise at least one of a lance, a burner or an injector at the periphery of the furnace and extending into the furnace.

4. The safety device as claimed in claim 1, further comprising the peripheral device of the arc furnace comprises an electrically operated plasma burner or a plasma injector which includes an outer layer comprising a metal shell which is electrically insulated from other burner parts in the furnace, and only the insulated metal shell part of the plasma injector is electrically connected to the safety device.

5. A method for protecting peripheral devices provided on an electric arc furnace wherein an earth line is provided to the peripheral devices, the method comprising, measuring a flow of current through the earth line, and, in the event of a critical current magnitude at one of the peripheral devices, breaking the earth line by a safety switch in the earth line within 100 ms of sensing the critical current magnitude, to interrupt formation of an arc at the one peripheral device.

6. An arc furnace, comprising:
a furnace body capable of containing a metal to be melted;
an arc electrode extending into the furnace body and operable to melt the metal to be melted;
a peripheral device supported at the periphery of the furnace body, and spaced from the metal to be melted and from the arc electrode, and configured and operable to perform a function involved with melting the metal;
the arc electrode is configured so that it may form an arc with the metal in the furnace or with one of the peripheral devices;
an earth line to the peripheral devices for grounding the peripheral devices; and
a safety device as claimed in claim 1; the safety switch is configured to monitor the earth line to determine if an arc is forming at one of the peripheral devices, and the safety switch is configured to trip open if an arc is forming.
